(19) United States
(12) Patent Application Publication
(10) Pub. No.: US 2015/0270324 A1
(43) Pub. Date: Sep. 24, 2015

(54) SEMICONDUCTOR DEVICE, DISPLAY UNIT, AND ELECTRONIC APPARATUS

(71) Applicant: Sony Corporation, Tokyo (JP)

(72) Inventor: Nobuhide Yoneya, Kanagawa (JP)

(21) Appl. No.: 14/416,538

(22) PCT Filed: Jul. 16, 2013
(86) PCT No.: PCT/JP2013/004345

§ 371 Date: Jan. 22, 2015

(30) Foreign Application Priority Data
Aug. 1, 2012 (JP) 2012-170796

(51) Int. Cl. H01L 27/32; H01L 51/05

(52) U.S. Cl. CPC H01L 27/3274; H01L 27/3248; H01L 51/0545; H01L 51/0533; H01L 27/3262; H01L 27/3265

(57) ABSTRACT

There is provided a semiconductor device including: a transistor (20T) including a first insulating film (23) between a gate electrode (21) and a semiconductor film (24), the first insulating film being in contact with at least the semiconductor film; and a storage capacitor (20C) including a second insulating film (22) between a pair of electrodes, the second insulating film having a dielectric constant higher than a dielectric constant of the first insulating film.

### TECHNICAL FIELD

The present technology relates to a semiconductor device, a display unit, and an electronic apparatus that are suitable for a case of using an organic semiconductor material for a semiconductor film.

### BACKGROUND ART

A Thin Film Transistor (TFT) is used as a drive device of many electronic apparatuses such as a display unit (semiconductor device). In recent years, as a semiconductor film of such a TFT, an organic material is promising in terms of cost, flexibility, and the like, and development thereof has been aggressively promoted (for example, NPL 1).

In the semiconductor device, a storage capacitor is provided together with the foregoing TFT. An insulating film exists between a gate electrode and a semiconductor film of the TFT, and between an upper electrode and a lower electrode of the storage capacitor. The insulating film is provided in the TFT and the storage capacitor in common.

### CITATION LIST

### Non Patent Literature

[NPL 1] J. Veres et al., Adv. Funct. Mater. 2003, 13, No. 3, March 199-204

### SUMMARY

### Technical Problem

In an electronic apparatus having the foregoing TFT and the foregoing storage capacitor, it is desirable to improve mobility of the TFT without decreasing the capacity of the storage capacitor.

It is desirable to provide a semiconductor device, a display unit, and an electronic apparatus in which mobility of a transistor is improved while the capacity of a storage capacitor is retained.

### Solution to Problem

According to an embodiment of the present technology, there is provided a semiconductor device including: a transistor including a first insulating film between a gate electrode and a semiconductor film, the first insulating film being in contact with at least the semiconductor film; and a storage capacitor including a second insulating film between a pair of electrodes, the second insulating film having a dielectric constant higher than a dielectric constant of the first insulating film.

According to an embodiment of the present technology, there is provided a display unit including: a plurality of pixels; a transistor driving the pixels, and including a first insulating film between a gate electrode and a semiconductor film, the first insulating film being in contact with at least the semiconductor film; and a storage capacitor including a second insulating film between a pair of electrodes, the second insulating film having a dielectric constant higher than a dielectric constant of the first insulating film.

According to an embodiment of the present technology, there is provided an electronic apparatus provided with a display unit. The display unit includes: a plurality of pixels; a transistor driving the pixels, and including a first insulating film between a gate electrode and a semiconductor film, the first insulating film being in contact with at least the semiconductor film; and a storage capacitor including a second insulating film between a pair of electrodes, the second insulating film having a dielectric constant higher than a dielectric constant of the first insulating film.

In the semiconductor device, the display unit, and the electronic apparatus according to the embodiments of the present technology, the first insulating film is provided in the transistor, and the second insulating film is provided in the storage capacitor. Therefore, the capacity of the storage capacitor is retained by the second insulating film having a high dielectric constant, and mobility of the transistor is improved by the first insulating film having a low dielectric constant.

### Advantageous Effect of Invention

According to the semiconductor device, the display unit, and the electronic apparatus according to the embodiments of the present technology, the first insulating film is provided in the transistor, and the second insulating film is provided in the storage capacitor. Therefore, mobility of the transistor is allowed to be improved, while the capacity of the storage capacitor is retained.

It is to be understood that both the foregoing general description and the following detailed description are exemplary, and are intended to provide further explanation of the technology as claimed.

### BRIEF DESCRIPTION OF DRAWINGS

FIG. 1 is a cross-sectional view illustrating a configuration of a display unit according to an embodiment of the present technology.

FIG. 2 is a diagram illustrating a whole configuration of the display unit illustrated in FIG. 1.

FIG. 3A is an equivalent circuit diagram illustrating an example of a pixel drive circuit illustrated in FIG. 2.

FIG. 3B is a diagram illustrating another example of the pixel drive circuit illustrated in FIG. 3A.

FIG. 4A is a cross-sectional view illustrating a method of manufacturing the display unit illustrated in FIG. 1.

FIG. 4B is a cross-sectional view illustrating a step following a step of FIG. 4A.

FIG. 4C is a cross-sectional view illustrating a step following the step of FIG. 4B.

FIG. 4D is a cross-sectional view illustrating a step following the step of FIG. 4C.

FIG. 5 is a cross-sectional view illustrating another example of the step following the step of FIG. 4B.

FIG. 6A is a cross-sectional view illustrating a step following the step of FIG. 4D.

FIG. 6B is a cross-sectional view illustrating a step following the step of FIG. 6A.

FIG. 6C is a cross-sectional view illustrating a step following the step of FIG. 6B.

FIG. 6D is a cross-sectional view illustrating a step following the step of FIG. 6C.

FIG. 7 is a cross-sectional view illustrating a configuration of a display unit according to a comparative example.

FIG. 8 is a cross-sectional view illustrating a configuration of a display unit according to a modification.

FIG. 9A is a perspective view illustrating an appearance of Application example 1.

FIG. 9B is a perspective view illustrating another example of FIG. 9A.

FIG. 10 is a perspective view illustrating an appearance of Application example 2.

FIG. 11 is a perspective view illustrating an appearance of Application example 3.

FIG. 12A is a perspective view illustrating an appearance viewed from the front side of Application example 4.

FIG. 12B is a perspective view illustrating an appearance viewed from the rear side of Application example 4.

FIG. 13 is a perspective view illustrating an appearance of Application example 5.

FIG. 14 is a perspective view illustrating an appearance of Application example 6.

FIG. 15A is a diagram illustrating Application example 7 in a closed state.

FIG. 15B is a diagram illustrating Application example 7 in an open state.

FIG. 16 is a cross-sectional view illustrating another example of the display unit illustrated in FIG. 1.

### DESCRIPTION OF EMBODIMENTS

A preferred embodiment of the present technology will be described in detail below with reference to the drawings. The description will be given in the following order.

1. Embodiment (a display unit having a first insulating film and a second insulating film: an example of a bottom-gate and top-contact type transistor)
2. Modification (an example of a top-gate and bottom-contact type transistor)

### Embodiment

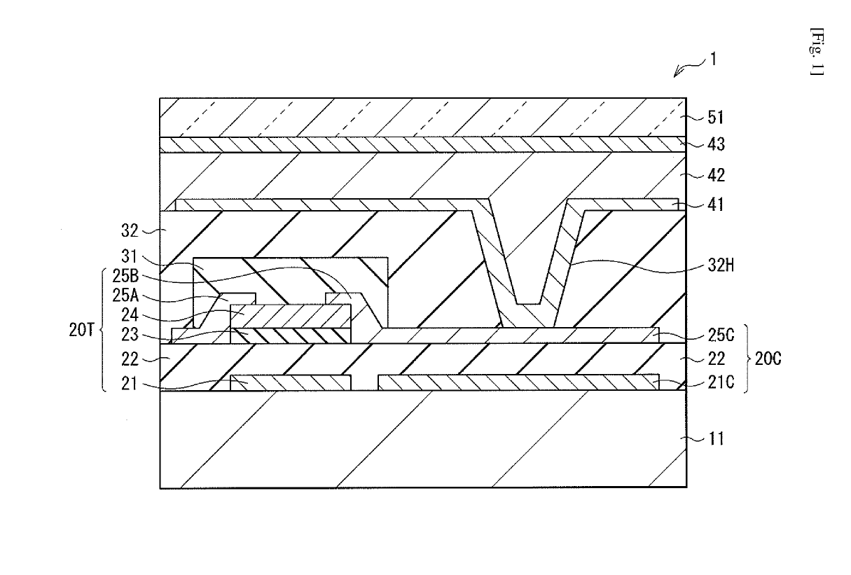

FIG. 1 illustrates a cross-sectional configuration of a display unit (display unit 1) according to an embodiment of the present technology. The display unit 1 (semiconductor device) is an active-matrix type display unit, and has a transistor 20T and a storage capacitor 20C on a substrate 11. The transistor 20T is a bottom-gate and top-contact type organic TFT, and has a gate electrode 21, a second insulating film 22, a first insulating film 23, a semiconductor film 24, and source-drain electrodes 25A and 25B in this order from the substrate 11 side. In the display unit 1, an interlayer insulating film 32, a pixel electrode 41, a display layer 42, a common electrode 43, and an opposed substrate 51 are further provided in this order above the transistor 20T and the storage capacitor 20C. It is to be noted that FIG. 1 schematically illustrates a structure of the display unit 1, and dimensions and shapes in FIG. 1 may be different from actual dimensions and actual shapes.

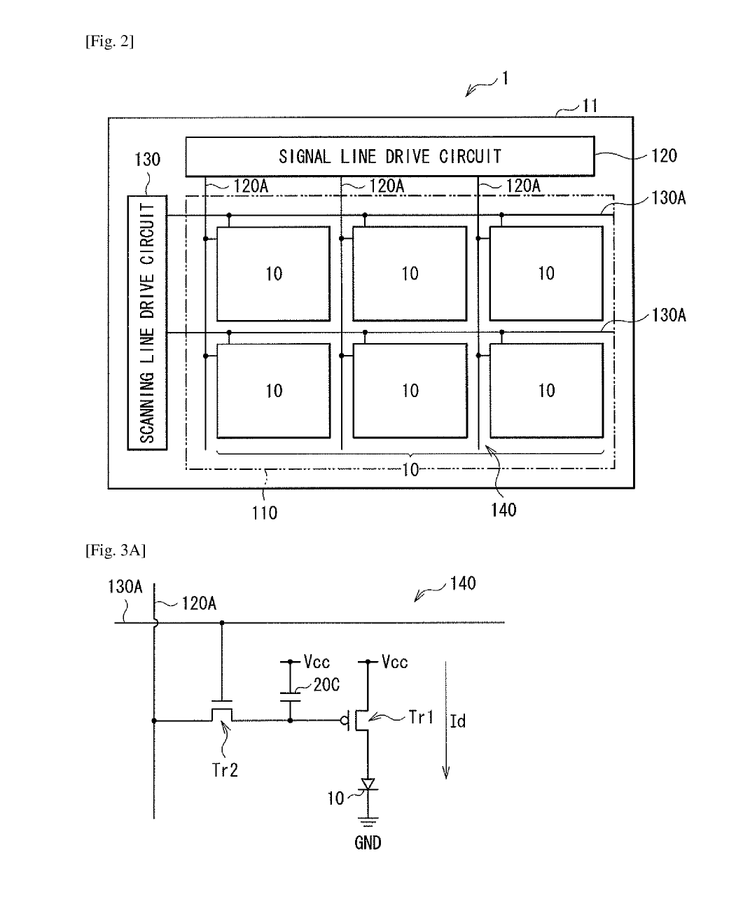

FIG. 2 illustrates a whole configuration of the display unit 1. In the display unit 1, a plurality of pixels 10 arranged in a state of matrix and various drive circuits for driving the pixels 10 are formed in a display region 110 on the substrate 11. On the substrate 11, as the drive circuits, for example, a signal line drive circuit 120 and a scanning line drive circuit 130 that are drivers for displaying an image and a pixel drive circuit 140 may be arranged.

FIG. 3A illustrates an example of an equivalent circuit diagram of the pixel drive circuit 140. The pixel drive circuit 140 is an active drive circuit in which the foregoing transistor 20T is arranged as either one or both of transistors Tr1 and Tr2. The storage capacitor 20 C is provided between the transistors Tr1 and Tr2, and the pixel 10 is serially connected to the transistor Tr1 between a first power line (Vcc) and a second power line (GND). In such a pixel drive circuit 140, a plurality of signal lines 120A are arranged in a column direction, and a plurality of scanning lines 130A are arranged in a row direction. Each of the signal lines 120A is connected to the signal line drive circuit 120. An image signal is supplied from the signal line drive circuit 120 to a source electrode of the transistor Tr2 through the signal line 120A. Each of the scanning lines 130A is connected to the scanning line drive circuit 130. A scanning signal is sequentially supplied from the scanning line drive circuit 130 to a gate electrode of the transistor Tr2 through the scanning line 130A. As illustrated in FIG. 3B, as a transistor of the pixel drive circuit 140, only the transistor Tr1 may be used.

Next, a description will be given of detailed configurations of the respective sections of the display unit 1 referring to FIG. 1 again. The substrate 11 may be formed of, for example, an inorganic material such as glass, quartz, silicon, and gallium arsenide; a film made of polyethylene terephthalate (PET), polyethylene naphthalate (PEN), polyether sulfone (PES), polyether imide, polyetherether ketone (PEEK), polyphenylene sulfide, polyarylate, polyimide (PI), polyamide, polycarbonate (PC), cellulose triacetate, polyolefin, polystyrene, polyethylene, polypropylene, polymethyl methacrylate (PMMA), polyvinyl chloride, polyvinylidene chloride, an epoxy resin, a phenol resin, a urea resin, a melamine resin, a silicone resin, an acryl resin, or the like; a metal foil; or the like. The substrate 11 may be a rigid substrate made of silicon or the like, or may be a flexible substrate configured of a thin layer glass, the foregoing plastic film, or the like. In the case where the substrate 11 is a flexible substrate, a bendable and flexible display is allowed to be achieved. The substrate 11 may have electric conductivity.

The gate electrode 21 applies a gate voltage to the transistor 20T, and controls carrier density in the semiconductor film 24 by the gate voltage to form a channel region. The gate electrode 21 is provided in a selective region on the substrate 11, and has a thickness, for example, from 10 nm to 1000 nm both inclusive (thickness in a lamination direction, and simply referred to as thickness below). The gate electrode 21 may be made of a metal element such as gold (Au), silver (Ag), copper (Cu), platinum (Pt), titanium (Ti), ruthenium (Ru), molybdenum (Mo), chromium (Cr), tungsten (W), nickel (Ni), aluminum (Al), and tantalum (Ta) or an alloy thereof. Further, the gate electrode 21 may have a laminated structure in which these metal films are layered. Further, the gate electrode 21 may be made of an oxide film such as indium tin oxide (ITO), indium zinc oxide (IZO), and zinc oxide (ZnO); a conductive carbon material such as carbon nanotube (CN) and graphene; or an organic conductive material formed of a conductive polymer such as PEDOT/PSS and polyaniline.

Between the gate electrode 21 and the semiconductor film 24, the second insulating film 22 and the first insulating film 23 are provided in this order from the gate electrode 21 side, and the first insulating film 23 is in contact with the semiconductor film 24. The planar shape of the first insulating film 23 is the same as the planar shape of the semiconductor film 24. Specifically, the first insulating film 23 is provided only in the transistor 20T. In contrast, the second insulating film 22 is provided in the transistor 20T and the storage capacitor 20C in common. The dielectric constant of the second insulating film 22 is higher than that of the first insulating film 23. In this embodiment, since the first insulating film 23 and the second insulating film 22 are provided, mobility of the transistor 20T is allowed to be improved while the capacity of the storage capacitor 20C is retained.

The first insulating film 23 and the second insulating film 22 insulate the gate electrode 21 from the semiconductor film 24 electrically connected to the source-drain electrodes 25A and 25B. The second insulating film 22 is provided on the whole surface of the substrate 11, and has a role to insulate a lower electrode 21C from an upper electrode 25C that are described later. For the second insulating film 22, a material having a dielectric constant (E) of 3 or more may be preferably used. Examples of such a material may include an organic insulating film that is added with a melamine-based cross-linking agent, such as PVP (polyvinylphenol, E=3.9), PMMA (E=3.5), PVA (polyvinyl alcohol, E=10), and PI (E=3.3). For the second insulating film 22, an inorganic material such as silicon oxide (SiOₓ, E=4), aluminum oxide (Al₂O₃, E=9.5), and silicon nitride (SiNₓ, E=7) may be used. The thickness of the second insulating film 22 may be, for example, from 100 nm to 1000 nm both inclusive. By providing the second insulating film 22 in the transistor 20T as well, the capacity of the transistor 20T is allowed to be prevented from being lowered.

The first insulating film 23 is provided between the second insulating film 22 and the semiconductor film 24, and is in contact with the semiconductor film 24 as described above. In the transistor 20T, since the first insulating film 23 is provided, the mobility is allowed to be improved without influencing the capacity value of the storage capacitor 20C. For the first insulating film 23, a material having a dielectric constant (E) of 3 or less may be preferably used. Examples of such a material may include an organic material such as CYTOP (registered trademark, available from Asahi Glass Co., Ltd., E=2.1), TOPAS (registered trademark, available from ADVANCED POLYMERS GmbH, E=2.3), and poly-alpha-methylstyrene (E=2.6). The first insulating film 23 may be preferably made of an organic insulating material. One reason for this is that, although details will be described later, in the case where the first insulating film 23 is made of an organic material, the first insulating film 23 and the semiconductor film 24 made of an organic material are phase-separated. It is preferable that TOPAS be used for the first insulating film 23, and PVP be used for the second insulating film 22. For the first insulating film 23, an inorganic material such as silicon oxide, aluminum oxide, and silicon nitride may be used, as long as the dielectric constant thereof is lower than that of the second insulating film 22. An oxide film may be provided on the respective surfaces of the first insulating film 23 and the second insulating film 22. The first insulating film 23 may be preferably thinner than the second insulating film 22, and the thickness thereof may be, for example, from 1 nm to 500 nm both inclusive.

The semiconductor film 24 is provided on the first insulating film 23, and has a channel region between the source-drain electrode 25A and the source-drain electrode 25B. The semiconductor film 24 is made of an organic semiconductor material such as an acene-based semiconductor such as pentacene, a peri-xanthenoxanthene derivative, and poly-3-hexylthiophene-2,5-diyl (P3HT). The thickness of the semiconductor film 24 may be, for example, from about 1 nm to about 1000 nm both inclusive.

The pair of source-drain electrodes 25A and 25B are in contact with the top surface of the semiconductor film 24 and are electrically connected thereto, and are provided from a portion on the semiconductor film 24 to a portion on the second insulating film 22. The source-drain electrodes 25A and 25B are in contact with the semiconductor film 24 on the side opposite to the first insulating film 23. For the source-drain electrodes 25A and 25B, a material similar to that of the foregoing gate electrode 21 may be used. Each thickness of the source-drain electrodes 25A and 25B may be, for example, from about 10 nm to about 1000 nm both inclusive.

On the source-drain electrodes 25A and 25B, a protective film 31 is provided so as to cover the semiconductor film 24. The protective film 31 prevents intrusion of moisture and oxygen into the semiconductor film 24. The protective film 31 is made of an organic insulating material such as CYTOP (registered trademark, available from Asahi Glass Co., Ltd.) and Fluorosurf (registered trademark, available from Fluoro Technology). The protective film 31 may be made of an inorganic insulating material such as silicon oxide, aluminum oxide, and silicon nitride.

The storage capacitor 20C is a capacitative element that is provided on the substrate 11 together with the transistor 20T and that retains electric charge in the pixel drive circuit 140 (FIG. 3A and FIG. 3B). The storage capacitor 20C has the lower electrode 21C in the same layer as that of the gate electrode 21, the second insulating film 22 shared with the transistor 22T, and the upper electrode 25C in the same layer as that of the source-drain electrodes 25A and 25B in this order from the substrate 11 side. The upper electrode 25C is integrated with the source-drain electrode 25B. The insulating film (the second insulating film 22) between the upper electrode 25C and the lower electrode 21A is configured of one layer, and the number of layers thereof is smaller than that of the insulating films (the first insulating film 23 and the second insulating film 22) between the semiconductor film 24 and the gate electrode 21 of the transistor 20T. As described above, in the storage capacitor 20C, since only the second insulating film 22 having a dielectric constant higher than that of the first insulating film 23 is provided between the pair of electrodes (the lower electrode 21C and the upper electrode 25C), a higher capacity is retained.

The interlayer insulating film 32 planarizes the surface of the substrate 11 on which the transistor 20T and the storage capacitor 20C are provided. The interlayer insulating film 32 has a connection hole 32H for conducting the source-drain electrode 25B (the upper electrode 25C) to the pixel electrode 41. For the interlayer insulating film 32, for example, an organic insulating material such as CYTOP (registered trademark, available from Asahi Glass Co., Ltd.) and Fluorosurf (registered trademark, available from Fluoro Technology), a posi/nega permanent resist, or the like may be used. The interlayer insulating film 32 may be made of an inorganic insulating material such as silicon oxide, aluminum oxide, and silicon nitride.

The pixel electrode 41 is provided on the interlayer insulating film 32 for every pixel, and applies a voltage to the display layer 42 with respect to the common electrode 43. The pixel electrode 41 may be made of, for example, a metal film such as gold, silver, copper, molybdenum, titanium, chromium, nickel, and aluminum; an oxide film such as ITO; a conductive carbon-based material film such as carbon nanotube and grapheme; or an organic conducive material such as PEDOT/PSS and polyaniline. The thickness of the pixel electrode 41 may be, for example, from about 10 nm to about 1000 nm both inclusive.

The display layer 42 is provided between the pixel electrode 41 and the common electrode 43, and is driven by the transistor 20T for every pixel. The display layer 42 may be configured of, for example, a liquid crystal layer, an organic EL (Electroluminescence) layer, an inorganic EL layer, an electrophoretic display, or the like. The common electrode 43 is common to the respective pixels, and may be, for example, provided on one surface of the opposed substrate 51. The common electrode 43 may be made of, for example, a transparent conductive material such as ITO. The thickness of the common electrode 43 may be, for example, from about 10 nm to about 1000 nm both inclusive.

The opposed substrate 51 may be made with the use of, for example, a material similar to that of the substrate 11. In the display unit 1, an image is displayed on the opposed substrate 51 side. On the opposed substrate 51, a moistureproof film for preventing moisture intrusion into the display layer 42, a film with optical functionality for preventing glare and reflection of outside light, and/or the like may be provided.

The display unit 1 as described above may be manufactured, for example, as follows.

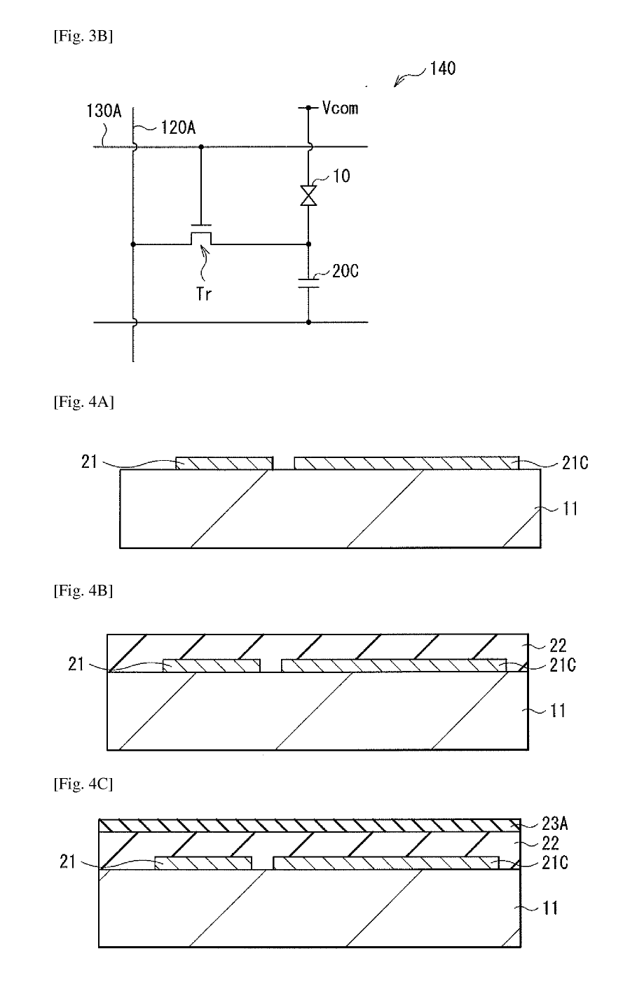

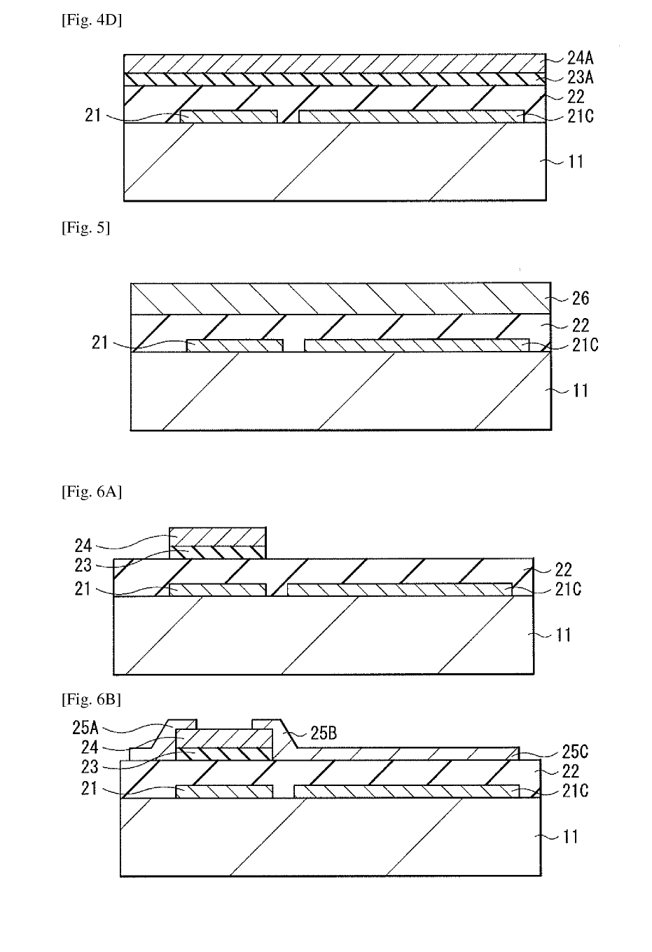

First, as illustrated in FIG. 4A, the gate electrode 21 and the lower electrode 21C are formed on the substrate 11. Specifically, the foregoing conductive film is formed on the whole surface of the substrate 11 with the use of a vacuum plasma technology such as an evaporation method and a sputtering method. Thereafter, the conductive film is patterned with the use of a photolithography technology, and therefore, the gate electrode 21 and the lower electrode 21C in desired shapes are formed. The gate electrode 21 and the lower electrode 21C may be formed with the use of a printing technology such as an offset printing method, an ink-jet method, and a screen printing method.

Next, on the substrate 11 including the top surfaces and the side surfaces of the gate electrode 21 and the lower electrode 21C, a film of an organic insulating material is formed with the use of a coating method such as a spin coating method and a slit coating method. Thereafter, the resultant film is patterned with the use of a photolithography technology to form the second insulating film 22 (FIG. 4B). The second insulating film 22 may be formed of a photosensitive resin material. Patterning may be performed with the use of laser ablation or the like. Further, the second insulating film 22 may be formed with the use of a printing technology such as an offset printing method, an ink-jet method, and a screen printing method. Alternatively, the second insulating film 22 may be formed by forming a film made of an inorganic insulating material such as silicon oxide, aluminum oxide, and silicon nitride with the use of a sputtering method, a CVD (Chemical Vapor Deposition) method, or the like.

Subsequently, as illustrated in FIG. 4C, on the second insulating film 22, a first insulating material film 23A made of an organic insulating material such as TOPAS is formed. For the first insulating material film 23A, a material having a dielectric constant lower than that of the second insulating film 22 is used. For forming the first insulating material film 23A, a method similar to that of the foregoing second insulating film 22 may be used.

After the first insulating material film 23A is formed, as illustrated in FIG. 4D, a semiconductor material film 24A made of an organic conductor material such as a peri-xanthenoxanthene derivative is formed with the use of a coating method such as spin coating method and a slit coating method. The semiconductor material film 24A may be formed with the use of a vapor-phase deposition method such as an evaporation method instead of the coating method.

Alternatively, the first insulating material film 23A and the semiconductor material film 24A may be provided by phase separation. Specifically, as illustrated in FIG. 5, first, the second insulating film 22 is coated with a mixed solution 26 obtained by dissolving respective constituent materials of the first insulating film 23 and the semiconductor film 24 such as TOPAS and peri-xanthenoxanthene in a solvent such as xylene by a spin coating method or the like. Next, the mixed solution 26 is baked and dried, and therefore, the organic semiconductor material and the organic insulating material are separated. Accordingly, the semiconductor material film 24A is formed in the upper layer and the first insulating material film 23A is formed in the lower layer (FIG. 4D). With the use of such a phase separation method, the first insulating material film 23A and the semiconductor material film 24A are allowed to be formed by one film-formation step. Further, in an interface between the first insulating material film 23A and the semiconductor material film 24A that is formed by the phase separation, carrier trapping is less likely to occur, and characteristics of the transistor 20T such as mobility and subthreshold characteristics (S value) are improved.

After the first insulating material film 23A and the semiconductor material film 24A are formed, the semiconductor material film 24A is patterned with the use of, for example, a photolithography technology to form the semiconductor film 24. For the patterning of the semiconductor material film 24A, laser ablation or the like may be used as well. Further, the semiconductor film 24 may be formed by forming a metal film on the semiconductor material film 24A, patterning the resultant film, and subsequently using the patterned metal film as a mask. Alternatively, the semiconductor film 24 that is directly patterned by a printing method such as an offset printing method, an ink-jet printing method, and a screen printing method may be formed on the first insulating material film 23A (FIG. 4C).

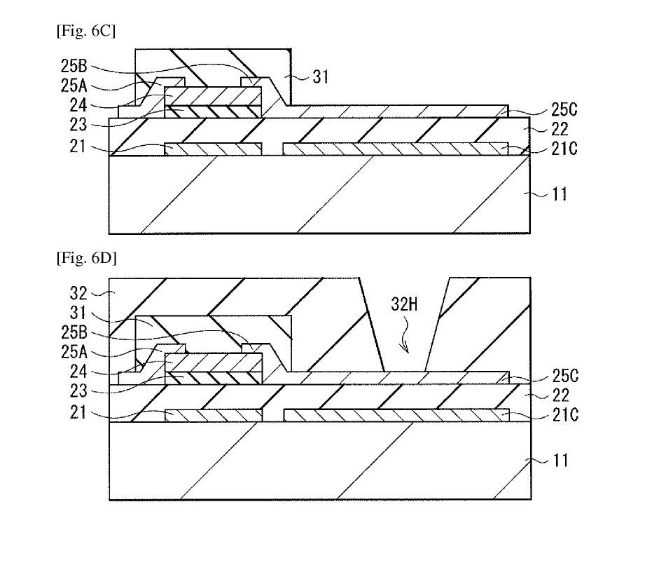

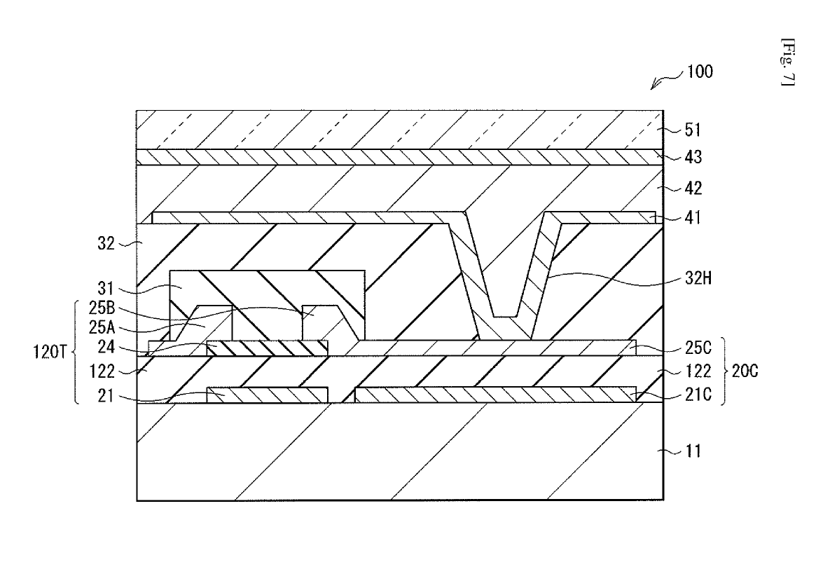

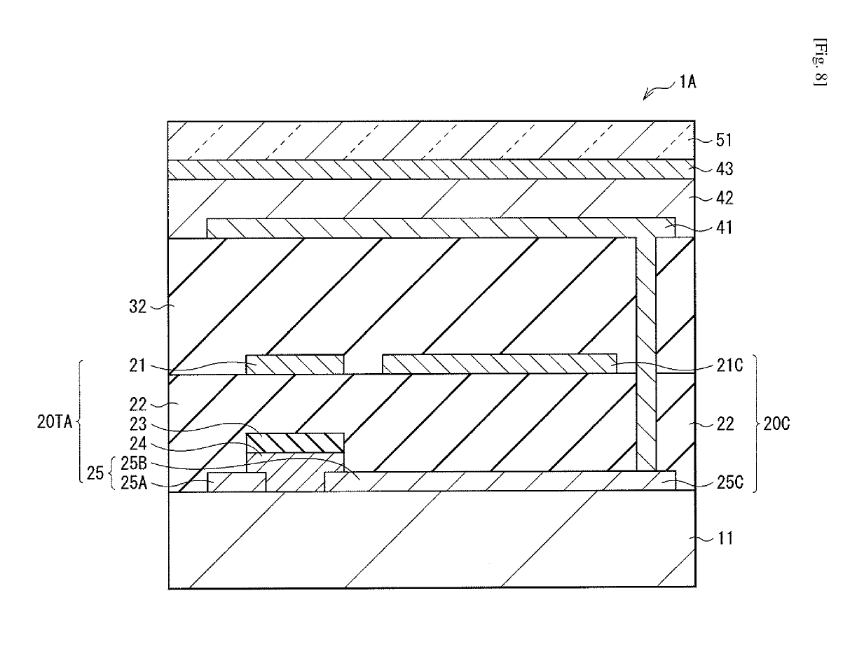

After the semiconductor film 24 is formed, as illustrated in FIG. 6A, the first insulating material film 23A may be patterned with the use of, for example, a photolithography technology to form the first insulating film 23. At this time, for example, the mask used for forming the semiconductor film 24 may be continuously used, and therefore, the first insulating material film 23A may be patterned. Therefore, the planar shape of the semiconductor film 24 becomes the same as the planar shape of the first insulating film 23, and the first insulating material film 23A on the lower electrode 21C is removed. In the case where the first insulating material film 23A is made of a photosensitive resin material, the first insulating film 23 may be formed without using a mask such as a resist. For the patterning of the first insulating material film 23A, laser ablation or the like may be used as well. Further, the first insulating material film 23A and the semiconductor material film 24A may be patterned at the same time. Further, the first insulating film 23 that is directly patterned by a printing method such as an offset printing method, an ink-jet printing method, and a screen printing method may be formed on the second insulating material film 22 (FIG. 4B). Further, the semiconductor film 24 (the semiconductor material film 24A) may be formed after the first insulating material film 23A is patterned.

After the semiconductor film 24 and the first insulating film 23 are formed, as illustrated in FIG. 6B, the source-drain electrodes 25A and 25B and the upper electrode 25C are formed. By this step, the transistor 20T and the storage capacitor 20C are formed on the substrate 11. The source-drain electrodes 25A and 25B and the upper electrode 25C may be formed by, for example, a method similar to that of the gate electrode 21 and the lower electrode 21C described above.

Subsequently, as illustrated in FIG. 6C, the protective film 31 is formed on the source-drain electrodes 25A and 25B including a gap (section where the semiconductor film 24 is exposed) between the source-drain electrode 25A and the source-drain electrode 25B. The protective film 31 may be formed by, for example, a method similar to that of the first insulating film 23 and the second insulating film 22 described above.

After the transistor 20T and the storage capacitor 20C are formed, the interlayer insulating film 32 is formed thereon, and the connection hole 32H may be formed with the use of, for example, a photolithography technology (FIG. 6D). In the case where the interlayer insulating film 32 is formed of a permanent resist, the connection hole 32H may be formed by a photolithography technology with the use of, for example, a photo mask. Alternatively, the connection hole 32H may be formed by laser ablation or the like. The interlayer insulating film 32 having the connection hole 32H may be formed by a printing method such as an offset printing method, an ink-jet printing method, and a screen printing method.

Subsequently, the pixel electrode 41 is formed on the interlayer insulating film 32 by patterning for every pixel, and the source-drain electrode 25B (the upper electrode 25C) and the pixel electrode 41 are electrically connected. The pixel electrode 41 may be formed by, for example, a method similar to that of the source-drain electrodes 25A and 25B.

After the pixel electrode 41 is formed, the display layer 42 is formed on the pixel electrode 41. Next, the opposed substrate 51 provided with the common electrode 43 is arranged oppositely to the display layer 42 and is fixed thereon. Through the foregoing steps, the display unit 1 illustrated in FIG. 1 is completed.

In the display unit 1 of this embodiment, the display layer 43 is driven by the transistor 20T for every pixel 10, and an image is displayed on the opposed substrate 51 side. In this case, the transistor 20T is provided with the first insulating film 23 together with the second insulating film 22, and the storage capacitor 20C is provided only with the second insulating film 22. Therefore, mobility of the transistor 20T is allowed to be improved while the capacity of the storage capacitor 20C is retained.

FIG. 7 illustrates a cross-sectional configuration of a display unit (display unit 100) according to a comparative example. In the display unit 100, only a second insulating film 122 exists between the gate electrode 21 and the semiconductor film 24, and the first insulating film is not provided. In other words, since an insulating film having a dielectric constant different from that of the second insulating film 122 is not provided in a transistor 120T of the display unit 100, mobility of the transistor 120T and the capacity of the storage capacitor 20C are not individually adjusted. It is reported that in a transistor, in particular, in an organic TFT using an organic semiconductor material, if the dielectric constant of an insulating film (gate insulating film) between a gate electrode and a semiconductor film is low, mobility of the transistor is improved (for example, NPL 1). In contrast, as the dielectric constant of an insulating film between a pair of electrodes is higher, the storage capacity becomes higher. Specifically, in the display unit 100, in the case where the dielectric constant of the second insulating film 122 is lowed, the capacity of the storage capacitor 20C is decreased, and therefore, mobility of the transistor 120T and the capacity of the storage capacitor 20C are not allowed to be improved at the same time. Further, the second insulating film 122 having a low dielectric constant increases a drive voltage of the display unit 100 as well.

In contrast, in the display unit 1, the first insulating film 23 having a low dielectric constant is provided only in the transistor 20T. Therefore, mobility of the transistor 20T is allowed to be improved while the capacity of the storage capacitor 20C is retained by providing the second insulating film 22 having a dielectric constant higher than that of the first insulating film 23 in the storage capacitor 20C. Further, in the storage capacitor 20C and the transistor 20T, high definition and shortened writing time are achieved, and image quality of the display unit 1 is allowed to be improved. Further, a drive voltage is allowed to be prevented from being increased.

As described above, in this embodiment, in addition to the second insulating film 22 common to the transistor 20T and the storage capacitor 20C, the first insulating film 23 is provided in the transistor 20T. Therefore, both the capacity of the storage capacitor 20C and the mobility of the transistor 20T are allowed to be improved. Further, since the interface between the semiconductor material film 24 (the semiconductor material film 24A) and the first insulating film 23 (the first insulating material film 23A) of the transistor 20T is formed by the phase separation, characteristics of the transistor 20T are allowed to be further improved.

A description will be given below of a modification of the foregoing embodiment. In the following description, for the same components as the components in the foregoing embodiment, the same referential symbols are affixed thereto, and the description thereof will be omitted as appropriate.

### Modification

FIG. 8 illustrates a cross sectional configuration of a display unit (display unit 1A) according to the modification of the foregoing embodiment. The display unit 1A has a top-gate and bottom-contact type transistor (transistor 20TA). Except for the foregoing point, the display unit 1A has a configuration similar to that of the display unit 1, and the operation and the effect thereof are similar to those of the display unit 1.

The transistor 20TA has the source-drain electrodes 25A and 25B, the semiconductor film 24, the first insulating film 23, the second insulating film 22, and the gate electrode 21 in this order from the substrate 11 side. The first insulating film 23 has the same planar shape as that of the semiconductor film 24, and is in contact with the semiconductor film 24. The second insulating film 22 covers the first insulating film 23, and is provided in common with the storage capacitor 20C. The source-drain electrodes 25A and 25B are in contact with the semiconductor film 24 on the side opposite to the first insulating film 23. In such a display unit 1A, the first insulating film 23 is provided only in the transistor 20TA, and the second insulating film 22 is provided between the pair of electrodes (the electrodes 21C and 25C) of the storage capacitor 20C. Therefore, while the capacity of the storage capacitor 20C is retained, mobility of the transistor 20TA is allowed to be improved.

The foregoing display units 1 and 1A may be mounted on, for example, electronic apparatuses illustrated in Application examples 1 to 7 described below.

### Application Example 1

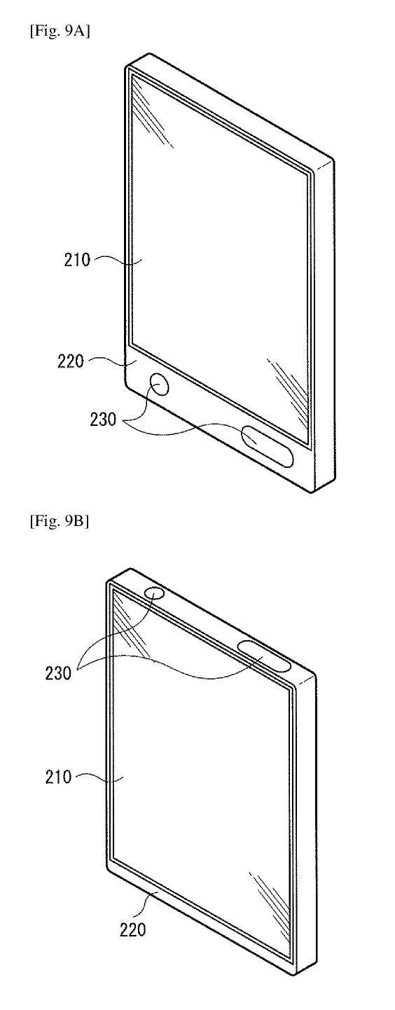

FIGS. 9A and 9B illustrate appearances of an electronic book reader. The electronic book reader may have, for example, a display section 210 and a non-display section 220, and an operation section 230 is provided in the non-display section 220. The display section 210 is configured of the foregoing display unit 1 or the foregoing display unit 1A. The operation section 230 may be formed on the same surface (front surface) as the surface on which the display section 210 is formed as illustrated in FIG. 9A. Alternately, the operation section 230 may be formed on a surface (top surface) different from the surface on which the display section 210 is formed as illustrated in FIG. 9B.

### Application Example 2

FIG. 10 illustrates an appearance of a tablet personal computer. The tablet personal computer may have, for example, a touch panel section 310 and a package 320. The touch panel section 310 is configured of the foregoing display unit 1 or the foregoing display unit 1A.

### Application Example 3

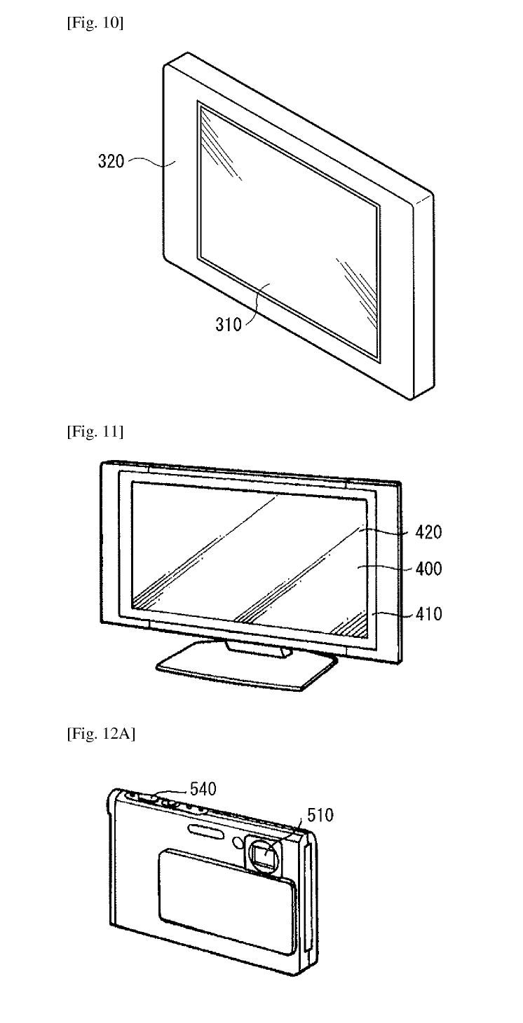

FIG. 11 illustrates an appearance of a television. The television may have, for example, an image display screen section 400 including a front panel 410 and a filter glass 420. The image display screen section 400 is configured of the foregoing display unit 1 or the foregoing display unit 1A.

### Application Example 4

FIGS. 12A and 12B each illustrate an appearance of a digital still camera. The digital still camera may have, for example, a light emitting section 510 for a flash, a display section 520, a menu switch 530, and a shutter button 540. The display section 520 is configured of the foregoing display unit 1 or the foregoing display unit 1A.

### Application Example 5

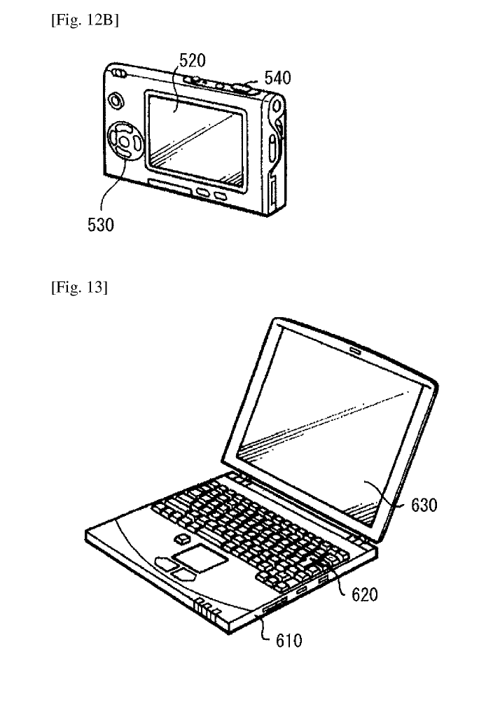

FIG. 13 illustrates an appearance of a notebook personal computer. The notebook personal computer may have, for example, a main body 610, a keyboard 620 for operation of inputting characters and the like, and a display section 630 for displaying an image. The display section 630 is configured of the foregoing display unit 1 or the foregoing display unit 1A.

### Application Example 6

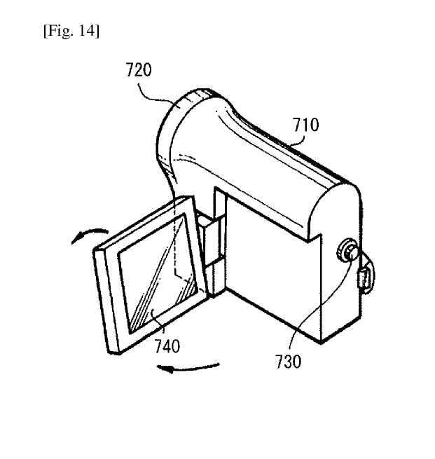

FIG. 14 illustrates an appearance of a video camcorder. The video camcorder may have, for example, a main body 710, a lens 720 for shooting a subject, provided on the front side surface of the main body 710, a start-stop switch 730 for shooting, and a display section 740. The display section 740 is configured of the foregoing display unit 1 or the foregoing display unit 1A.

### Application Example 7

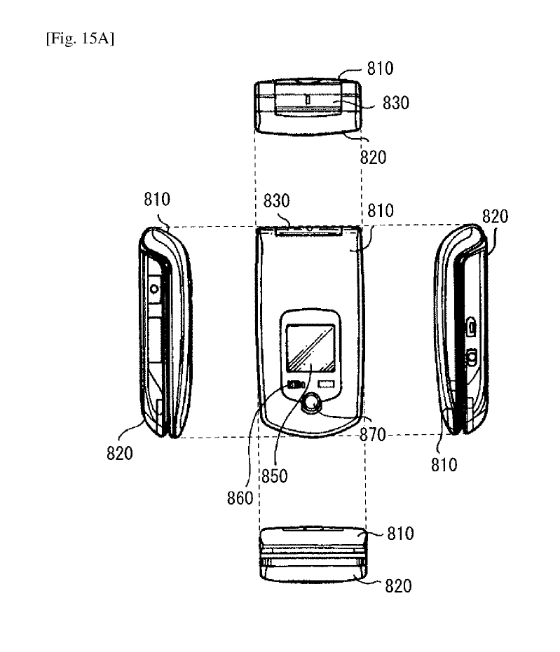

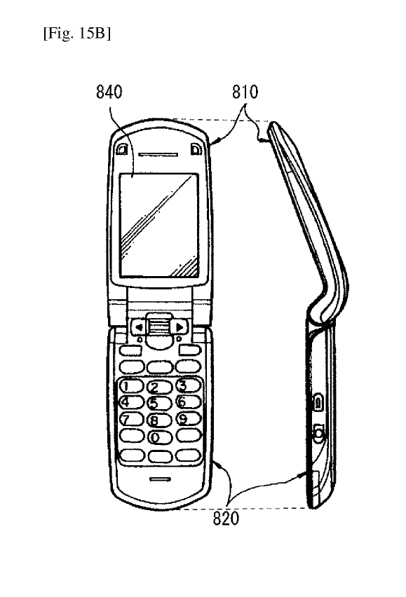

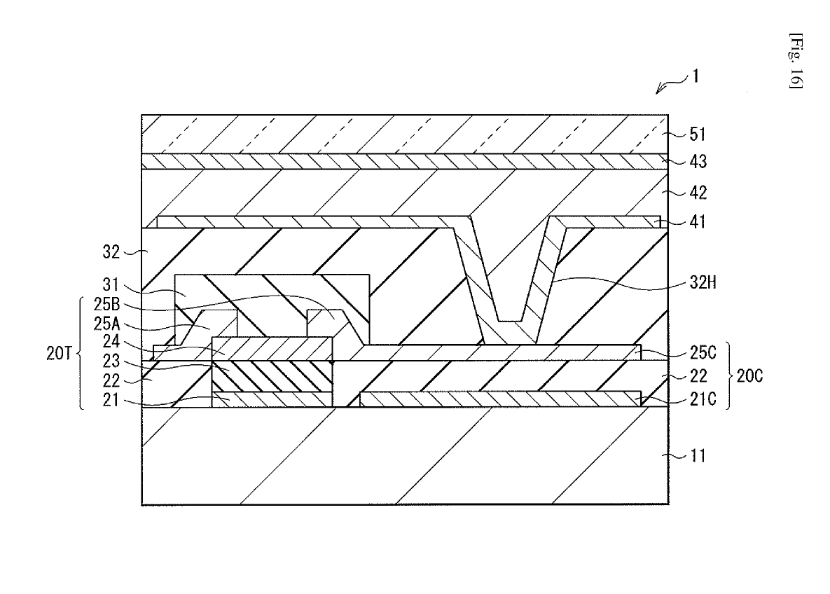

FIGS. 15A and 15B each illustrate an appearance of a mobile phone. In the mobile phone, for example, an upper package 810 and a lower package 820 may be jointed by a joint section (hinge section) 830. The mobile phone may have a display 840, a sub-display 850, a picture light 860, and a camera 870. Either one or both of the display 840 and the sub-display 850 are configured of the foregoing display unit 1 or the foregoing display unit 1A.

While the present technology has been described with reference to the preferred embodiment and the modification, the present technology is not limited to the foregoing embodiment and the like, and various modifications may be made. For example, in the foregoing embodiment and the like, the description has been given of the bottom-gate and top-contact type transistor 20T and the top-gate and bottom-contact type transistor 20TA. However, the present technology is also applicable to a bottom-gate and bottom-contact type transistor and a top-gate and top-contact type transistor. Further, it is sufficient that the first insulating film 23 is provided only in the transistor 20T, and the planar shape thereof may be different from the planar shape of the semiconductor film 24.

Further, in the foregoing embodiment and the like, the description has been given of the case in which the semiconductor film is made of the organic semiconductor material as an example. However, the semiconductor film may be made of an inorganic material such as silicon and oxide semiconductor.

Further, in the foregoing embodiment and the like, the description has been given of the case in which the two insulating films (the second insulating film 22 and the first insulating film 23) are provided between the gate electrode 21 and the semiconductor film 24 of the transistor 20T, and one insulating film (the second insulating film 22) is provided between the pair of electrodes of the storage capacitor 20C. However, three or more insulating films may be provided in the transistor 20T, and two or more insulating films may be provided in the storage capacitor 20C. Further, as illustrated in FIG. 16, only the first insulating film 23 may be provided between the gate electrode 21 and the semiconductor film 24 of the transistor 20T.

Furthermore, for example, the material, the thickness, the film-forming method, the film-forming conditions, and the like of each layer are not limited to those described in the foregoing embodiment, and other material, other thickness, other film-forming method, and other film-forming conditions may be adopted.

It is to be noted that the technology may be configured as follows.
(1) A semiconductor device including:
a transistor including a first insulating film between a gate electrode and a semiconductor film, the first insulating film being in contact with at least the semiconductor film; and
a storage capacitor including a second insulating film between a pair of electrodes, the second insulating film having a dielectric constant higher than a dielectric constant of the first insulating film.
(2) The semiconductor device according to (1), wherein
the second insulating film is provided in the storage capacitor and the transistor in common, and
the second insulating film and the first insulating film are included between the gate electrode and the semiconductor film.
(3) The semiconductor device according to (1) or (2), wherein a planar shape of the first insulating film is the same as a planar shape of the semiconductor film.
(4) The semiconductor device according to any one of (1) to (3), further including source-drain electrodes electrically connected to the semiconductor film.
(5) The semiconductor device according to (4), wherein
the transistor includes the gate electrode, the first insulating film, and the semiconductor film in this order from a substrate side, and
the source-drain electrodes are in contact with the semiconductor film on a side opposite to the first insulating film.
(6) The semiconductor device according to (4), wherein
the transistor includes the semiconductor film, the first insulating film, and the gate electrode in this order from a substrate side, and
the source-drain electrodes are in contact with the semiconductor film on a side opposite to the first insulating film.
(7) The semiconductor device according to any one of (1) to (6), wherein the first insulating film and the semiconductor film are made of organic materials, and are phase-separated from each other.
(8) The semiconductor device according to (4), wherein one of the source-drain electrodes is integrated with one of the electrodes of the storage capacitor.
(9) The semiconductor device according to (2), wherein the first insulating film is thinner than the second insulating film.
(10) A display unit including:
a plurality of pixels;
a transistor driving the pixels, and including a first insulating film between a gate electrode and a semiconductor film, the first insulating film being in contact with at least the semiconductor film; and
a storage capacitor including a second insulating film between a pair of electrodes, the second insulating film having a dielectric constant higher than a dielectric constant of the first insulating film.
(11) An electronic apparatus provided with a display unit, the display unit including:
a plurality of pixels;
a transistor driving the pixels, and including a first insulating film between a gate electrode and a semiconductor film, the first insulating film being in contact with at least the semiconductor film; and
a storage capacitor including a second insulating film between a pair of electrodes, the second insulating film having a dielectric constant higher than a dielectric constant of the first insulating film.

The present disclosure contains subject matter related to that disclosed in Japanese Priority Patent Application JP 2012-170796 filed in the Japan Patent Office on Aug. 1, 2012, the entire contents of which is hereby incorporated by reference.

It should be understood by those skilled in the art that various modifications, combinations, sub-combinations and alternations may occur depending on design requirements and other factors insofar as they are within the scope of the appended claims or the equivalents thereof.

### REFERENCE SIGNS LIST

1, 1A display unit
10 pixel
11 substrate
20T, 20TA transistor
20C storage capacitor
21 gate electrode
21C lower electrode
22 second insulating film
23 first insulating film
24 semiconductor film
25A, 25B source-drain electrode
25C upper electrode
31 protective film
32 interlayer insulating film
32H connection hole
41 pixel electrode
42 display layer
43 common electrode
51 opposed substrate
110 display region
120 signal line drive circuit
130 scanning line drive circuit
140 pixel drive circuit
Tr1, Tr2 transistor

1. A semiconductor device comprising:
a transistor including a first insulating film between a gate electrode and a semiconductor film, the first insulating film being in contact with at least the semiconductor film; and
a storage capacitor including a second insulating film between a pair of electrodes, the second insulating film having a dielectric constant higher than a dielectric constant of the first insulating film.

2. The semiconductor device according to claim 1, wherein
the second insulating film is provided in the storage capacitor and the transistor in common, and
the second insulating film and the first insulating film are included between the gate electrode and the semiconductor film.

3. The semiconductor device according to claim 1, wherein a planar shape of the first insulating film is the same as a planar shape of the semiconductor film.

4. The semiconductor device according to claim 1, further comprising source-drain electrodes electrically connected to the semiconductor film.

5. The semiconductor device according to claim 4, wherein
the transistor includes the gate electrode, the first insulating film, and the semiconductor film in this order from a substrate side, and
the source-drain electrodes are in contact with the semiconductor film on a side opposite to the first insulating film.

6. The semiconductor device according to claim 4, wherein
the transistor includes the semiconductor film, the first insulating film, and the gate electrode in this order from a substrate side, and
the source-drain electrodes are in contact with the semiconductor film on a side opposite to the first insulating film.

7. The semiconductor device according to claim 1, wherein the first insulating film and the semiconductor film are made of organic materials, and are phase-separated from each other.

8. The semiconductor device according to claim 4, wherein one of the source-drain electrodes is integrated with one of the electrodes of the storage capacitor.

9. The semiconductor device according to claim 2, wherein the first insulating film is thinner than the second insulating film.

10. A display unit comprising:
a plurality of pixels;
a transistor driving the pixels, and including a first insulating film between a gate electrode and a semiconductor film, the first insulating film being in contact with at least the semiconductor film; and
a storage capacitor including a second insulating film between a pair of electrodes, the second insulating film having a dielectric constant higher than a dielectric constant of the first insulating film.

11. An electronic apparatus provided with a display unit, the display unit comprising:
a plurality of pixels;
a transistor driving the pixels, and including a first insulating film between a gate electrode and a semiconductor film, the first insulating film being in contact with at least the semiconductor film; and
a storage capacitor including a second insulating film between a pair of electrodes, the second insulating film having a dielectric constant higher than a dielectric constant of the first insulating film.
